(19) United States
(12) Patent Application Publication
(10) Pub. No.: US 2010/0258952 A1
(43) Pub. Date: Oct. 14, 2010

(54) Interconnection of IC Chips by Flex Circuit Superstructure

(75) Inventor: Joseph C. Fjelstad, Maple Valley, WA (US)

Correspondence Address: TPL/Interconnect Portfolio, LLC;C/O Alliacense Limited LLC, 20883 Stevens Creek Boulevard, Suite 100, Cupertino, CA, 95014, US

(73) Assignee: INTERCONNECT PORTFOLIO LLC, Cupertino, CA (US)

(21) Appl. No.: 12/755,961

(22) Filed: Apr. 7, 2010

Related U.S. Application Data
(60) Provisional application No. 61/167,790, filed on Apr. 8, 2009.

(51) Int. Cl. H01L 23/498

(52) U.S. Cl. 257/778; 257/E23.06

(57) ABSTRACT

Integrated circuit chips have top and bottom surfaces. The bottom surfaces comprise a plurality of IC die terminals in flip-chip assembly with fine-pitch terminals formed on the top surface of corresponding interconnection substrate. Each IC chip includes one or more through-silicon vias and/or edge wrap connectors that extend to the top surface, terminating in IC die terminals. Flexible connectors are coupled between the IC die terminals on the top surfaces of corresponding first and second integrated circuit chips. The flexible connectors are preferably controlled impedance, and may include differential pairs, including twisted pairs, coaxial pairs, and broadside pairs. Conductive vias within the interconnection substrates couple the fine-pitch terminals to corresponding next-level terminals on the bottom surface of the respective interconnection substrates. The next level terminals of the interconnection substrates are interconnected with terminals of a printed circuit board.

### CROSS-REFERENCE TO RELATED APPLICATIONS

This application claims benefit of priority of U.S. Provisional Patent Application No. 61/167,790, filed Apr. 8, 2009. U.S. Provisional Patent Application No. 61/167,790 is incorporated by reference in its entirety herein.

### BACKGROUND OF THE INVENTION

1. Field of the Invention

The present invention relates generally to the field of semiconductor device manufacturing, and more particularly to an improved structure and method of interconnection between chips in a multi chip module or between IC packages.

2. Description of the Background Art

Electronic assemblies, including pluralities of integrated circuit chips, are widely used in electronic systems. A broad range of packaging and electrical interconnection techniques are used in such assemblies, including multichip modules (MCM) or system in package (SiP). These devices are then mounted onto an interconnection substrate such as a printed circuit board (PCB). With advances in semiconductor technology, the feature size of integrated circuits has decreased and the operating speed has increased, and the trend is expected to continue in the future. For highest operating speed, it is desirable to have short traces and wires interconnecting the elements of an integrated circuit, both on a single chip and between the terminals of chips in a MCM or SiP. The spacing or distance between the terminals of an electronic device, such as an integrated circuit chip, chip carrier, a packaged circuit, or a circuit board, is conventionally referred to as pad pitch. To improve yield and reduce the overall cost of assembly, it is desirable to have large pad pitch for the package assembly (e.g. MCM or SiP) at the circuit board level. Thus, integrated circuit chips having small feature size and small pad pitch are often first mounted on an interconnection substrate or carrier, and then the chip and substrate are mounted on a circuit board having large pad pitch. The interconnection substrate distributes the terminals to a larger pad pitch matching circuit board technology. The conflicting requirements of short interconnection length and large pad pitch explain the wide range of techniques used in the art, and drive the continuing development of new approaches to find optimum packaging and assembly solutions.

### BRIEF DESCRIPTION OF THE DRAWINGS

FIG. 1 is a side plan view of a first embodiment of the invention.

FIG. 2 is a side plan view of a second embodiment of the invention.

FIG. 3 is a side plan view of a third embodiment of the invention.

### DETAILED DESCRIPTION OF THE INVENTION

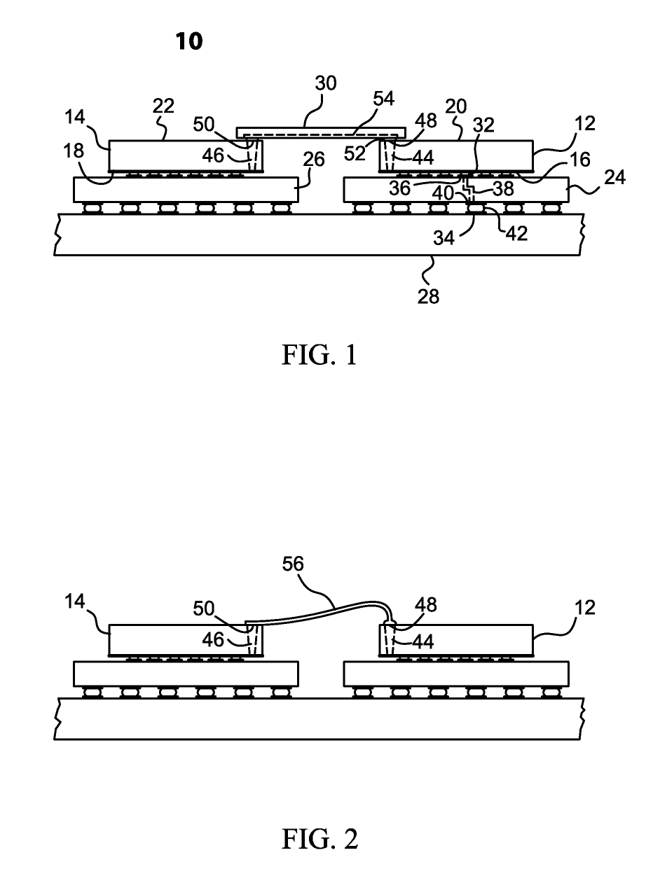

An embodiment of a new, improved means for interconnecting terminals of different chips of an electronic assembly, such as a multi chip module, is illustrated in FIG. 1, which depicts a multi chip module embodiment 10 in fragmentary side elevation view comprised of at least two IC chips, IC packages or MCMs mounted on a next level interconnection substrate. The module 10 includes integrated circuit chips 12, 14, each having a circuit side 16, 18, which includes a plurality of input/output terminals of the chip, and a “top” side 20, 22 facing in an opposite direction as the circuit side. The circuit side 16, 18 of each of the IC chips is mounted on a corresponding chip package substrate 24, 26. The embodiment depicted in FIG. 1 utilizes conventional flip-chip technology. For clarity of illustration, the embodiment of FIG. 1 depicts a single IC chip per chip package substrate, but embodiments are envisioned in which multiple chips are attached to each chip package substrate. The circuit side and “top” side surfaces are often described in terms of their orientation in a particular drawing, and such references are not intended to limit the appended claims, nor are they typically intended to limit the interpretation of other depictions. Flip-chip technology is widely known in the art and involves mounting an integrated circuit chip with its circuit side facing the substrate, sometimes also referred to as face-down orientation, and electrically connecting the terminals of a chip, which are located on the circuit side, to matching terminals or contact pads on the substrate, by means of solder balls, solder bumps, or other conductive materials (e.g. isotropic and anisotropic conductive adhesives), and by heat, ultrasonic bonding, or thermo sonic bonding. The circuit side 16, 18 of the chips 12, 14 of FIG. 1 are denoted in heavy line. In the interest of clarity, the terminals and other integrated circuit elements that are formed on the circuit side of the IC chips 12, 14 are not shown.

The module 10 further includes a next level interconnection substrate (e.g. a circuit board or higher level module substrate) 28 to which the IC package or MCM substrates 24, 26 are mounted. As described further below, the module 10 also includes a flex circuit or rigid superstructure between at least two IC chips 12, 14. The flex circuit or rigid superstructure is preferably a controlled-impedance structure. Although the following discussion is expressed in terms of electrical interconnections, this is offered for simplicity and verbal economy. The reader will readily appreciate that the embodiments depicted in FIGS. 1 and 2 can equally be adapted to optical data transmission from the “top” side or edge of an IC die. In electrical applications, each conductive path of the flex circuit or rigid superstructure is preferably a controlled impedance circuit path, and may include differential pairs, including twisted pairs, coaxial pairs, and broadside pairs.

A conventional electrical connection path between a terminal of the chip 12 adjacent a solder ball 32, and for example, a trace or contact terminal 34 of the circuit board 28, employing flip-chip technology, includes the solder ball 32, connected to an upper terminal 36 of substrate 24, a conductive path 38 through the substrate connected to a lower terminal 40 of the substrate, and a solder ball 42 connected to the terminal 34, on the circuit board or next level interconnection substrate. Electrical connections between other terminals of chips 12, 14 and contact terminals on substrate 28 are implemented through similar paths. Thus, it is easy to see with reference to FIG. 1 that an interconnection between a terminal of chip 12 and a terminal of chip 14 must proceed via two such paths, which are rather long and tortuous and therefore introduce both capacitance and series inductance into the circuit, and also electromagnetic coupling to neighboring connection paths.

According to an embodiment of the invention, an electrical connection between a terminal of chip 12 and a terminal of chip 14 is made by means of the flex circuit superstructure 30 shown in FIG. 1 in side view, and through-chip via connectors 44 and 46 in chips 12 and 14, respectively, which are shown in phantom in the figure. Such electrical connection bypasses completely the packaging substrate and can operate at higher speed and at lower power than a connection through the circuit board. Via connectors are known in the art and described, for example, in Jan Vardaman, “3-D Through-Silicon Vias Become a Reality”, Semiconductor International, No. 6, Jun. 1, 2007, which is incorporated by reference herein. The via connector 44 abuts and electrically connects to a terminal on the circuit side 16 of chip 12, and includes a conductive path through the chip, and has a contact surface or rear terminal 48 on the rear side of chip 12. The via connector 46 similarly connects a terminal on the circuit side of chip 14 to a contact surface or rear terminal 50 on the rear side of chip 14. The rear terminal 48 of via connector 44 is connected by any suitable means, such as a solder ball 52, to one end of a controlled impedance trace or wire 54 in flex circuit 30, and the rear terminal 50 of via connector 46 is similarly connected to the other end of the controlled-impedance wire 54, thereby completing an electrical connection between the terminal of chip 12 and the terminal of chip 14.

In an alternate embodiment illustrated in FIG. 2, an electrical connection between the rear terminal 48 of via connector 44 and the rear terminal 50 of via connector 46 is implemented by bond wire 56. The wire is shown to have a wedge bond at terminal 50 and a ball bond at terminal 48. Alternatively, the wire 56 can have a stitch bond at terminal 48, resulting in a lower physical profile. In still other embodiments, a double wire (i.e., differential pair) or multiple wires in parallel (including twisted pairs) and micro coaxial cable can be employed in place of wire 56, according to the electrical characteristics desired in the connection. In the case of the micro coaxial cable, ground connections could be made to ground contacts away from the signal contact on one or both of the chips.

An important feature of the inventive flex circuit superstructure interconnection employing through-chip via connectors is better access for inspection and rework, as the superstructure connection is physically separated from the flip-chip connections of the chips. It also makes the design of the package and base assembly less difficult by separating the critical signals from the non critical signals. While the structure is shown attending primarily to signals, power may be advantageously provided using an overarching metal sheet to access vias which serve the power function, thus providing clean power to all similarly prepared chips.

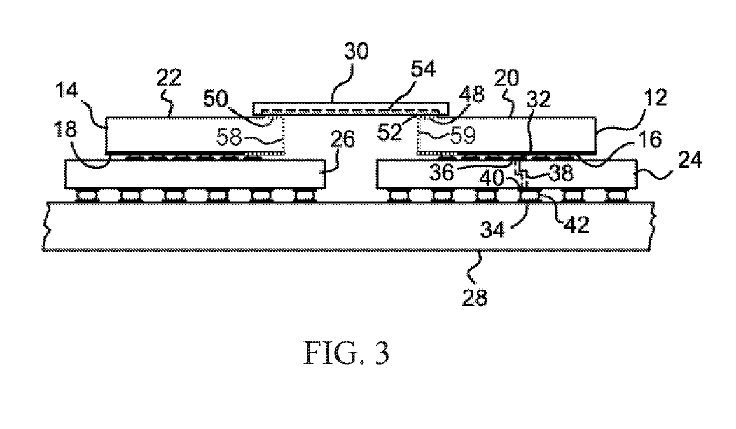

FIG. 3 depicts an alternative embodiment to the embodiments of FIGS. 1 and 2. In place of the through-silicon vias 44, 46 of FIGS. 1 and 2, wrap-around connections 58, 59 at the edges of the chips are used to connect terminals on the circuit side 16, 18 of chip 12, 14 to corresponding contacts 48, 50 on the rear side 20, 22 of chip 12, 14. The terminals on the rear side of the chips are interconnected by a flex circuit 30 in the same manner as discussed in conjunction with FIGS. 1 and 2. Edge connections such as the ChipScale™ edge wrap connection method, can be used, which is disclosed by Chen, et al., (U.S. Pat. No. 5,910,687), and Richards, et al., (U.S. Pat. No. 5,656,547), both of which are incorporated by reference in their entirety herein. Within FIG. 3, a conductive path 38 within interconnection substrate 24 connects the fine pitch terminals 36 on the top surface of the interconnection substrate with next-level terminals 40 on the bottom surface of the interconnection substrate. The next-level terminals are electrically coupled with circuit board terminals 34 by means of solder balls.

What is claimed is:

1. An electrical assembly comprising:
a first IC chip having top and bottom surfaces, a plurality of bottom side die terminals on the bottom surface, and a first through-silicon via terminating at a first top-side die terminal formed on the top surface of the first IC chip;
a first interconnection substrate with top and bottom surfaces and a first plurality of fine-pitch terminals disposed on a top surface, the first plurality of fine-pitch terminals of the first interconnection substrate being coupled in flip-chip connection with corresponding bottom-side die terminals of the first IC chip;
a second IC chip having top and bottom surfaces, a plurality of bottom side die terminals on the bottom surface, and a second through-silicon via terminating at a second top-side die terminal formed on the top surface of the second IC chip;
a second interconnection substrate with top and bottom surfaces and a second plurality of fine-pitch terminals disposed on a top surface, the second plurality of fine-pitch terminals being coupled in flip-chip connection with corresponding bottom-side die terminals of the second IC chip; and,
a first flexible circuit coupling the first top side die terminal and the second top side die terminal.

2. The electrical assembly of claim 1, the first chip further comprising a third through-silicon via terminating at a third top-side die terminal on the top surface of the first chip.

3. The electrical assembly of claim 2, the second chip further comprising a fourth through-silicon via terminating at a fourth top-side die terminal on the top surface of the second chip; and,
a second flexible circuit coupling the third top side die terminal and the fourth top side die terminal.

4. The electrical assembly of claim 2, the second chip further comprising a first edge-wrap connector extending from the bottom surface of the second chip to the top surface of the second chip, and terminating at a fourth top-side die terminal on the top surface of the second chip; and,
a second flexible circuit coupling the third top side die terminal and the fourth top side die terminal.

5. The electrical assembly of claim 1, the first chip further comprising a first edge-wrap connector extending from the bottom surface of the first chip to the top surface of the second chip, and terminating at a third top-side die terminal on the top surface of the first chip;
the second chip further comprising a second edge-wrap connector extending from the bottom surface of the second chip to the top surface of the second chip, and terminating at a fourth top-side die terminal on the top surface of the second chip; and,
a second flexible circuit coupling the third top side die terminal and the fourth top side die terminal.

6. The electrical assembly of claim 1, wherein the flexible circuit is an exposed bond-wire encapsulated in epoxy.

7. The electrical assembly of claim 1, wherein the flexible circuit comprises a conductive wire formed within a flexible insulating sheath.

8. The electrical assembly of claim 1, wherein the flexible circuit comprises a conductive wire formed within a flexible insulating sheath.

9. The electrical assembly of claim 1 wherein the flexible circuit is coupled to the first top-side die terminal in a wedge bond.

10. The electrical assembly of claim 1 wherein the flexible circuit is coupled to the first top-side die terminal in a ball bond.

11. The electrical assembly of claim 1 wherein the flexible circuit is coupled to the first top-side die terminal in a stitch bond.

12. The electrical assembly of claim 3, wherein the first and second flexible circuit couplings are a differential pair.

13. The electrical assembly of claim 4, wherein the first and second flexible circuit couplings are a differential pair.

14. The electrical assembly of claim 5, wherein the first and second flexible circuit couplings are a differential pair.

15. The electrical assembly of claim 1, further comprising a printed circuit board with a first plurality of circuit board terminals coupled to a second plurality of circuit board terminals through a corresponding plurality of circuit traces wherein;
the first interconnection substrate further comprises a first plurality of package terminals on the bottom surface and a first plurality of conductive vias coupling the first plurality of package terminals to the first plurality of fine pitch terminals; and,
the second interconnection substrate comprises a second plurality of package terminals on the bottom surface and a second plurality of conductive vias coupling the second plurality of package terminals to the second plurality of fine pitch terminals.

16. An electrical assembly comprising:
a first IC chip having top and bottom surfaces, a plurality of bottom side die terminals on the bottom surface, and a first through-silicon via terminating at a first top-side die terminal formed on the top surface of the first IC chip;
a first interconnection substrate with top and bottom surfaces and a plurality of fine-pitch terminals disposed on a top surface, the fine-pitch terminals of the first interconnection substrate being coupled in flip-chip connection with the bottom-side die terminals of the first IC chip;
a second IC chip having top and bottom surfaces, a plurality of bottom side die terminals on the bottom surface, and a first edge-wrap connector extending from the bottom surface and terminating at a second top-side die terminal formed on the top surface of the second IC chip;
a second interconnection substrate with top and bottom surfaces and a plurality of fine-pitch terminals disposed on a top surface, the fine-pitch terminals being coupled in flip-chip connection with the bottom-side die terminals of the second IC chip; and,
a first flexible circuit coupling the first top side die terminal and the second top side die terminal.

17. The electrical assembly of claim 16, further comprising a third or second? flexible circuit coupled between a third top side terminal on the first IC chip and a fourth top-side terminal on the second IC chip.

18. The electrical assembly of claim 16, further comprising a printed circuit board with a first plurality of circuit board terminals coupled to a second plurality of circuit board terminals through a corresponding plurality of circuit traces wherein;
the first interconnection substrate further comprises a first plurality of package terminals on the bottom surface and a first plurality of conductive vias coupling the first plurality of package terminals to the first plurality of fine pitch terminals; and,
the second interconnection substrate comprises a second plurality of package terminals on the bottom surface and a second plurality of conductive vias coupling the second plurality of package terminals to the second plurality of fine pitch terminals.

19. An electrical assembly comprising:
a first IC chip having top and bottom surfaces, a plurality of bottom side die terminals on the bottom surface, and a first edge-wrap connector extending from the bottom surface of the first IC chip and terminating at a first top-side die terminal formed on the top surface of the first IC chip;
a first interconnection substrate with top and bottom surfaces and a plurality of fine-pitch terminals disposed on a top surface, the fine-pitch terminals of the first interconnection substrate being coupled in flip-chip connection with the bottom-side die terminals of the first IC chip;
a second IC chip having top and bottom surfaces, a plurality of bottom side die terminals on the bottom surface, and a second edge-wrap connector extending from the bottom surface and terminating at a second top-side die terminal formed on the top surface of the second IC chip;
a second interconnection substrate with top and bottom surfaces and a plurality of fine-pitch terminals disposed on a top surface, the fine-pitch terminals being coupled in flip-chip connection with the bottom-side die terminals of the second IC chip; and,
a first flexible circuit coupling the first top side die terminal and the second top side die terminal.

20. The electrical assembly of claim 19, further comprising a second flexible circuit coupled between a third top side terminal on the first IC chip and a fourth top-side terminal on the second IC chip.

21. The electrical assembly of claim 19, further comprising a printed circuit board with a first plurality of circuit board terminals coupled to a second plurality of circuit board terminals through a corresponding plurality of circuit traces wherein;
the first interconnection substrate further comprises a first plurality of package terminals on the bottom surface and a first plurality of conductive vias coupling the first plurality of package terminals to the first plurality of fine pitch terminals; and,
the second interconnection substrate comprises a second plurality of package terminals on the bottom surface and a second plurality of conductive vias coupling the second plurality of package terminals to the second plurality of fine pitch terminals.

22. Apparatus comprising:
a printed circuit board;
at least two substrates flip chip mounted on said printed circuit board;
an integrated circuit chip flip chip mounted on each of said substrates, the integrated circuit chips having top surfaces; and
means for connecting signals between the top surfaces of respective of said integrated circuit chips.
